(19) United States
(12) Patent Application Publication
(10) Pub. No.: US 2017/0322337 A1
(43) Pub. Date: Nov. 9, 2017

(54) EVALUATION OF FORMATION MECHANICAL PROPERTIES USING MAGNETIC RESONANCE

(71) Applicants: Umesh Prasad, Spring, TX (US); Satya Perumalla, Dubai (AE); Daniel Moos, Palo Alto, CA (US)

(72) Inventors: Umesh Prasad, Spring, TX (US); Satya Perumalla, Dubai (AE); Daniel Moos, Palo Alto, CA (US)

(73) Assignee: Baker Hughes Incorporated, Houston, TX (US)

(21) Appl. No.: 15/144,903

(22) Filed: May 3, 2016

(51) Int. Cl. G01V 3/32; G01R 33/50

(52) U.S. Cl. CPC G01V 3/32; G01R 33/50

(57) ABSTRACT

An embodiment of an apparatus for estimating properties of an earth formation includes a carrier configured to be deployed in a borehole in the earth formation, a nuclear magnetic resonance (NMR) measurement device including a transmitting assembly configured to emit a pulse sequence into a region of a sedimentary earth formation, a receiving assembly configured to detect NMR signals in response to the pulse sequence, and a processor configured to receive the NMR signals and estimate one or more mechanical properties of the region. The processor is configured to perform calculating a size distribution based on the NMR signals, the size distribution including at least one of a pore size distribution and a grain size distribution in the region, estimating a strength of the region based on the size distribution, and performing one or more aspects of an energy industry operation based on the strength.

### BACKGROUND

Understanding the characteristics of geologic formations and fluids located therein is important for effective hydrocarbon exploration and production. Operations such as drilling, formation evaluation and production rely on accurate petrophysical interpretation derived from a diverse set of logging technologies.

For example, estimates of formation mechanical properties are critical for proper planning and execution of various energy industry operations. Knowledge of strength and/or stiffness of rock formations is important for operations such as drilling and evaluation, and brittleness and sweet spot estimates are important for completion and production phases of energy extraction.

### SUMMARY

An embodiment of an apparatus for estimating properties of an earth formation includes a carrier configured to be deployed in a borehole in the earth formation, a nuclear magnetic resonance (NMR) measurement device including a transmitting assembly configured to emit a pulse sequence into a region of a sedimentary earth formation, a receiving assembly configured to detect NMR signals in response to the pulse sequence, and a processor configured to receive the NMR signals and estimate one or more mechanical properties of the region. The processor is configured to perform calculating a size distribution based on the NMR signals, the size distribution including at least one of a pore size distribution and a grain size distribution in the region, estimating a strength of the region based on the size distribution, and performing one or more aspects of an energy industry operation based on the strength.

An embodiment of a method of estimating properties of an earth formation includes receiving NMR signals generated by a nuclear magnetic resonance (NMR) measurement device disposed in a carrier in a region of a sedimentary earth formation, the NMR measurement device including a transmitting assembly configured to emit a pulse sequence into a region of a sedimentary formation, and a receiving assembly configured to detect the NMR signals in response to the pulse sequence. The method also includes calculating a size distribution based on the NMR signals, the size distribution including at least one of a pore size distribution and a grain size distribution in the region, estimating a strength of the region based on the size distribution, and performing one or more aspects of an energy industry operation based on the strength.

### BRIEF DESCRIPTION OF THE DRAWINGS

The subject matter which is regarded as the invention is particularly pointed out and distinctly claimed in the claims at the conclusion of the specification. The foregoing and other features and advantages of the invention are apparent from the following detailed description taken in conjunction with the accompanying drawings in which:

FIG. 1 depicts an embodiment of a formation measurement system that includes a nuclear magnetic resonance (NMR) measurement apparatus;

FIG. 2 is a flow chart that depicts an embodiment of a method of performing NMR measurements and estimating mechanical properties of a formation;

FIG. 3 depicts an example of a T₂ distribution derived from NMR measurements and a grain size distribution estimated based on the T₂ distribution;

FIG. 4 depicts an example of a grain size distribution log;

FIG. 5 depicts an example of functions that describe relationships between grain size and porosity;

FIG. 6 depicts an example of functions that describe relationships between porosity and strength properties; and

FIG. 7 depicts an example of functions that describe relationships between grain size and strength properties.

FIG. 8 depicts an example of an integrated log;

FIG. 9 depicts an example of NMR data associated with the log of FIG. 8; and

FIG. 10 depicts an example of log data that includes formation mechanical property data.

### DETAILED DESCRIPTION

Methods, systems and apparatuses for measuring mechanical properties of an earth formation using magnetic resonance techniques are described herein. Embodiments of apparatuses, systems and methods utilize nuclear magnetic resonance (NMR) measurements to estimate mechanical properties of a formation. An embodiment of a method includes deriving grain size information (e.g., grain size, pore size and/or grain size distributions) from NMR measurements and using the grain size information to estimate mechanical properties including strength and/or stiffness. The strength and/or stiffness may be estimated based on NMR-derived grain size and porosity data also generated based on NMR measurements.

The mechanical properties may be used for various purposes, including planning and executing various energy industry operations. For example, the estimated strength and/or stiffness are used for geomechanical modeling, formation evaluation and planning of drilling, stimulation and production. Brittleness and/or sweet spot estimations may be used, e.g., for landing and hydraulic fracturing for tight sandstone.

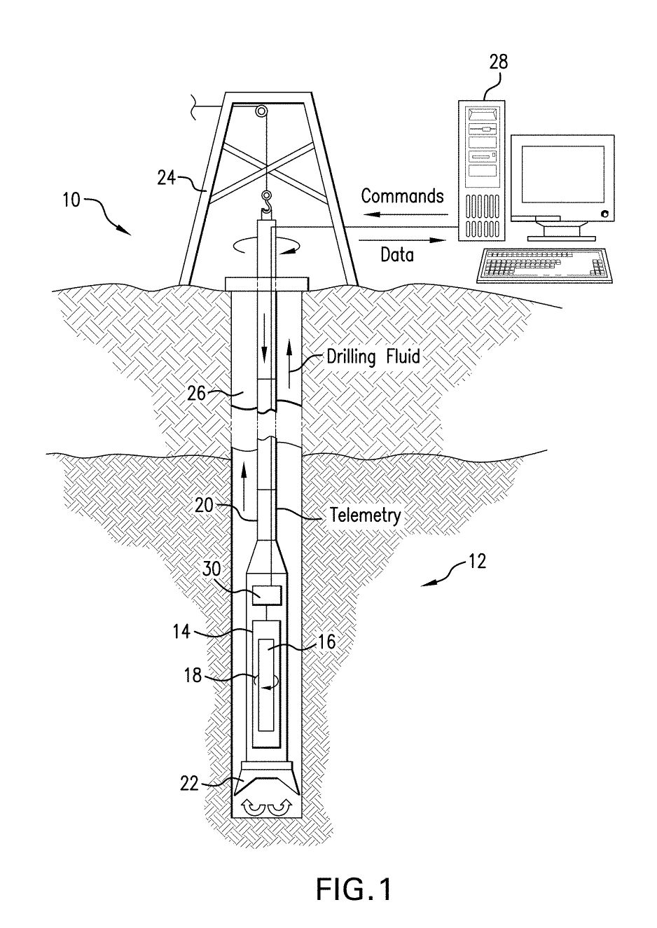

FIG. 1 illustrates an exemplary embodiment of a downhole measurement, data acquisition, and/or analysis system 10 that includes devices or systems for in-situ measurement of characteristics of an earth formation 12. The system 10 includes a magnetic resonance apparatus such as an NMR tool 14. An example of the magnetic resonance apparatus is a logging-while-drilling (LWD) magnetic resonance tool. The tool 14 is configured to generate magnetic resonance data for use in estimating characteristics of a formation, such as porosity, irreducible water saturation, permeability, hydrocarbon content, and fluid viscosity.

An exemplary tool 14 includes a static magnetic field source 16, such as a permanent magnet assembly, that magnetizes formation materials and a transmitter and/or receiver assembly 18 (e.g., an antenna or antenna assembly) that transmits radio frequency (RF) energy or pulsed energy that provides an oscillating magnetic field in the formation, and detects NMR signals as voltages induced in the receiver. The transmitter assembly 18 may serve the receive function, or distinct receiving antennas may be used for that purpose. It can be appreciated that the tool 14 may include a variety of components and configurations as known in the art of nuclear magnetic resonance or magnetic resonance imaging.

The tool 14 may be configured as a component of various subterranean systems, such as wireline well logging and LWD systems. For example, the tool 14 can be incorporated within a drill string 20 including a drill bit 22 or other suitable carrier and deployed downhole, e.g., from a drilling rig 24 into a borehole 26 during a drilling operation. The tool 14 is not limited to the embodiments described herein, and may be deployed in a carrier with alternative conveyance methods. A “carrier” as described herein means any device, device component, combination of devices, media and/or member that may be used to convey, house, support or otherwise facilitate the use of another device, device component, combination of devices, media, and/or member. Exemplary non-limiting carriers include drill strings of the coiled tube type, of the jointed pipe type, and any combination or portion thereof. Other carrier examples include casing pipes, wired pipes, wirelines, wireline sondes, slickline sondes, drop shots, downhole subs, bottom-hole assemblies, and drill strings.

In one embodiment, the tool 14 and/or other downhole components are equipped with transmission equipment to communicate ultimately to a surface processing unit 28. Such transmission equipment may take any desired form, and different transmission media and methods may be used, such as wired, fiber optic, mud pulse telemetry and/or other wireless transmission methods. Additional processing units may be deployed with the carrier. For example, a downhole electronics unit 30 includes various electronic components to facilitate receiving signals and collect data, transmitting data and commands, and/or processing data downhole. The surface processing unit 28, electronics 30, the tool 14, and/or other components of the system 10 include devices as necessary to provide for storing and/or processing data collected from the tool 14 and other components of the system 10. Exemplary devices include, without limitation, at least one processor, storage, memory, input devices, output devices, and the like.

Magnetic resonance measurements are performed by the NMR tool 14, which generates a static magnetic field (B₀) in a volume within the formation (a “volume of interest”) using one or more magnets (e.g., the magnetic field source 16). An oscillating (e.g., RF) magnetic field (B₁) is generated, which is at least substantially perpendicular to the static magnetic field in the volume of interest. The volume of interest may be circular or toroidal around the borehole, and/or focused or directed toward a specific angular region (i.e., side-looking).

When exposed to the magnetic field B₀, the spin axes of hydrogen nuclei in the formation process around the direction of the B₀ field with the Larmor frequency, which is proportional to the strength of the magnetic field B₀. The direction of orientation of the field B₀ in the formation volume of interest is referred to as the longitudinal direction or z-direction.

Over time, the spin axes align themselves at distinct angles along the B₀ field and create a net magnetization (i.e., polarization), which will build up with the time constant T₁, referred to as a longitudinal relaxation or spin lattice relaxation time. T₂ is a time constant of the transversal relaxation, which describes the loss of magnetization in the plane orthogonal to the B₀ field.

The B₁ field is typically applied as a sequence of short-duration pulses, referred to as a “pulse sequence” or “data gathering sequence”. The pulses may be rectangular or other shaped. A pulse sequence is used to measure T₂ relaxation, and may also indirectly used for the measurement of the T₁ relaxation. In an embodiment of a pulse sequence, the first pulse is a “tipping pulse”, which acts to align the nuclear magnetization in the formation in a direction perpendicular to the static field B₀, e.g., rotate the magnetization from the z-direction into the x-y plane. After the tipping pulse, the nuclear magnetization disperses in the x-y plane due to a spread of precession frequencies caused by B₀ field inhomogeneity and gradually returns or “relaxes” to its alignment with the static field.

At a selected time after the tipping pulse, one or more “refocusing pulses” are applied, which have a duration and amplitude selected to at least partly reverse the magnetizations of microscopic volume elements. In consequence the coherent macroscopic magnetization that was lost after the tipping pulse rephases after each refocus pulse, resulting in so-called spin echoes that induce a measurable voltage in the receiving antenna.

In one embodiment, the pulse sequence is a dual-wait-time (DTW) measurement. In a DTW configuration, a transmitting assembly is configured to emit pulse sequences that include at least a first pulse sequence having a first wait time and a second pulse sequence having a second wait time into a formation volume of interest. A receiving assembly detects echo trains (referred to herein as “long-wait-time echo trains”) based on the first pulse sequence, and also detects echo trains (referred to herein as “short-wait-time echo trains”) based on the second pulse sequence.

The surface processing unit 28, electronics 30 and/or other suitable processing device includes a processor configured to perform NMR measurements of a region or volume of interest in a formation (e.g., surrounding the borehole 26) and/or estimate mechanical properties of the formation based on the NMR measurements.

Although the system 10 is shown as including a drill string, it is not so limited and may have any configuration suitable for performing an energy industry operation. For example, the system 10 may be configured as a hydraulic stimulation system. As described herein, “stimulation” may include any injection of a fluid into a formation. An exemplary stimulation system may be configured as a cased or open hole system for initiating fractures and/or stimulating existing fractures in the formation. A fluid may be any flowable substance such as a liquid or a gas, and/or a flowable solid such as sand. In this example, the system. Another example includes a production system including a production string and flow control devices such as inflow control valves.

Systems and/or processors described herein (e.g., the surface processing unit 28) are configured to evaluate mechanical properties of an earth formation based on NMR measurements. In one embodiment, the systems and/or processors are configured to evaluate properties of unconventional formations such as sandstone and/or shale formations. As discussed further below, the T₂ response of a formation is used to directly detect pore size or grain size distributions, and may also be analyzed to estimate porosity. Mechanical properties such as strength and stiffness are derived based on the porosity and/or grain size distribution.

In one embodiment, the systems and/or processors are also configured to estimate brittleness and detect sweet spots or potential intervals for purposes such as hydraulic fracturing and selection of production zones based on the T₂ response.

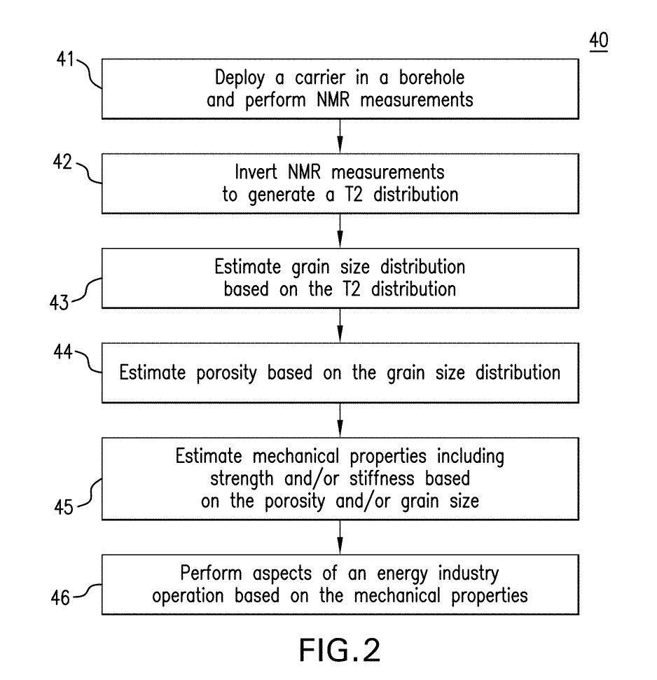

FIG. 2 illustrates a method 40 of performing NMR measurements and estimating mechanical properties of a formation. The method 40 may be performed in conjunction with the system 10, but is not limited thereto. The method 40 includes one or more of stages 41-46 described herein, at least portions of which may be performed by a processor (e.g., the surface processing unit 28). In one embodiment, the method 40 includes the execution of all of stages 41-46 in the order described. However, certain stages 41-46 may be omitted, stages may be added, or the order of the stages changed.

In the first stage 41, an NMR or other magnetic resonance measurement tool is deployed into a borehole. In one embodiment, the tool (e.g., the tool 14) is deployed as part of a wireline operation, or during drilling as part of an LWD operation. The speed at which the NMR device is advanced is referred to as logging speed.

Measurements are performed by generating a static magnetic field B₀ in a volume or region of interest in the formation, and transmitting pulsed signals from at least one transmitting antenna, which in turn generate an oscillating magnetic field B₁ in the region of interest. At least one receiving antenna detects NMR signals from the volume in response to the interaction between the nuclear spins of interest and the static and oscillating magnetic fields, and generates NMR data. The NMR data includes spin echo trains that may be measured at a plurality of depths.

Output from each measurement is detected as time domain amplitude measurements generated by each pulse sequence. The time domain amplitude values for a pulse sequence are referred to as an echo train, in which the echo amplitude decreases with the time constant T₂.

In one embodiment, the formation includes sedimentary rock materials such as sandstone, shale, oil shale, limestone, siltstone and others. The formation may include various combinations of sedimentary rock materials, such as varying amounts of sand, silt, quartz and clay. In one embodiment, the formation includes an unconventional type of formation including, e.g., sandstone (such as clean sandstone, silty sandstone and/or shaly sandstone), argillaceous sand, silt with intercalated shale layers and/or silty-shale. It is noted that the method 40 is not limited to the types of formations discussed herein, but may be used in conjunction with any type of formation that includes grain structures.

In the second stage 42, measured data including raw echo trains are processed to calculate a measured T₂ distribution by inverting the data from the time domain (echo train data) into the T₂ domain (T₂ distribution).

In one embodiment, the T₂ distribution is divided into two or more volume fractions, or fractions of the pore space volume. Each volume fraction is associated with a T₂ value range. For example, the T₂ distribution is divided into two volumetrics: a fraction of the pore space fluid volume or volume fraction associated with short-T₂ values (referred to as a “short-T₂” fluid or a “short-T₂ porosity fraction”), and a fraction of the pore space fluid volume or volume fraction associated with long-T₂ values (referred to as a “long-T₂” fluid or a “long-T₂ porosity fraction”). Short-T₂ fluids are fluids or combinations of fluids corresponding to T₂ values or a portion of a T₂ distribution below a selected threshold or cutoff, and long-T₂ fluids are fluids corresponding to T₂ values or a portion of a T₂ distribution at or above the cutoff.

For example, a cutoff splits the T₂ porosity distribution into two volumetrics: a short-T₂ porosity fraction associated with bound water (referred to as T_{2w}), and a long-T₂ porosity fraction associated with long-T₂ fluid such as free fluids (e.g., gas and/or light oil).

In the third stage 43, grain size is estimated based on the T₂ distribution. For example, the T₂ distribution is calibrated using empirical data, simulations and/or other information derived from borehole and/or surface measurements of formation materials around the borehole, around another borehole and/or in a similar formation.

In one embodiment, the grain size distribution is calculated by inputting T₂ values to a structural rock model. The model is applied to construct a grain size distribution that shows the relative frequency of grain size values. The grain size distribution includes a frequency value (also referred to as intensity) associated with each grain size. The grain size distribution may be analyzed to generate a range of grain sizes or a single grain size value for a given depth, for example, by calculating an average or mean of the grain sizes, based on statistical analysis, by calculating a mathematical function, or by any other suitable technique for generating representative grain size values.

The model correlates T₂ values to grain size values. The model may also take into consideration additional information, such as mineralogy, partial water saturation, surface relaxivity and surface roughness of the grains.

An example of a structural model and method used to calculate grain size distribution is described in conjunction with the following example. In this example, an initial grain size distribution is generated with a log-normal or Weibull distribution. The following equations show a tri-modal incremental grain size distribution f(X) and a cumulative grain size distribution P(X):

$$\begin{matrix}f ( X ) = {\sum }_{i = 1}^{3} {α}_{i} \frac{{β}_{i}}{{γ}_{i}} {( \frac{X}{{γ}_{i}} )}^{{β}_{i} - 1} exp ( - {( \frac{X}{{γ}_{i}} )}^{{β}_{i}} ) & \\ X > 0 , {α}_{i} > 0 , {β}_{i} > 0 , {γ}_{i} > 0 , {\sum }^{ } {α}_{i} = 1 & ( 1 ) \\ P ( X ) = {\sum }_{i = 1}^{3} {α}_{i} ( 1 - exp ( - {( \frac{X}{{γ}_{i}} )}^{{β}_{i}} ) , & ( 2 )\end{matrix}$$

where βᵢ is a shape factor at an increment i, γᵢ is a scale factor, αᵢ is the intensity, and X is a value defined by a ratio of grain size to a minimum grain size. X may be defined as:

$$X = ln ( \frac{{r}_{g}}{{r}_{g , 0}} ) , \qquad ( 3 )$$

where r_{g} is the grain size, and r_{g,0} and is the selected minimum grain size.

The initial distribution is input to a structural model to simulate the T₂ response of water in the formation, referred to as T_{2w,s} and the final grain size distribution is determined by minimizing the error between the simulated t_{2w,s} and the bound water volumetric from the measured T₂ distribution (T_{2w,m}). For example, the grain size g is calculated based on the following:

$$g ( {α}_{j} , {β}_{j} , {γ}_{j} ) = min ( {\sum }_{i = 1}^{n} {( {f}_{i , s} - {f}_{i , m} )}^{2} ) , \qquad ( 4 )$$

where f_{i,s} and f_{i,m} are the intensity of the i^{th} bin in the simulated T_{2w,s} and measured T_{2w,m}, respectively.

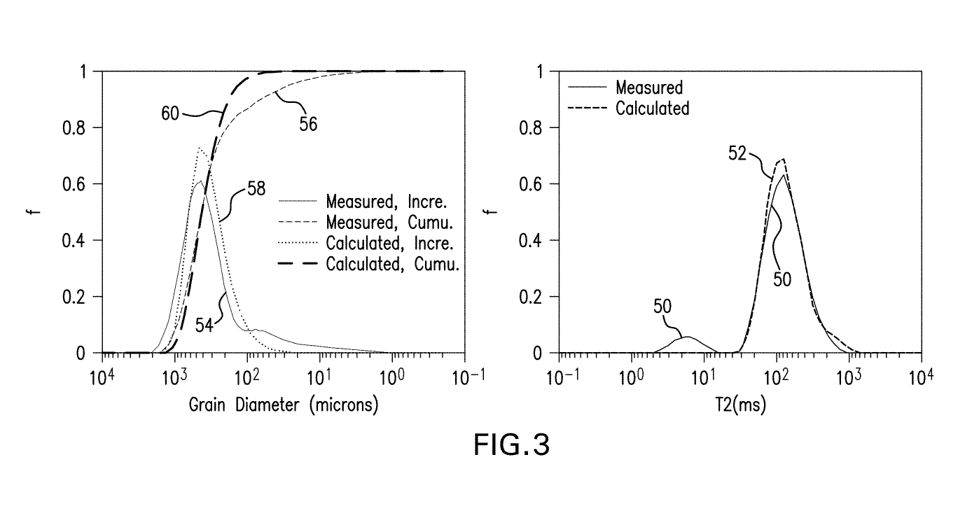

FIG. 3 illustrates an example of a T₂ distribution 50 calculated from NMR measurements, in comparison with a simulated T2 distribution 52. The T₂ distributions are plotted as a function of frequency or intensity (f) of T₂ values. A grain size distribution 54 calculated according to the above method is shown along with a cumulative distribution 56. Also shown are a simulated grain size distribution 58 and simulated cumulative distribution 60 to demonstrate the efficacy of the above method.

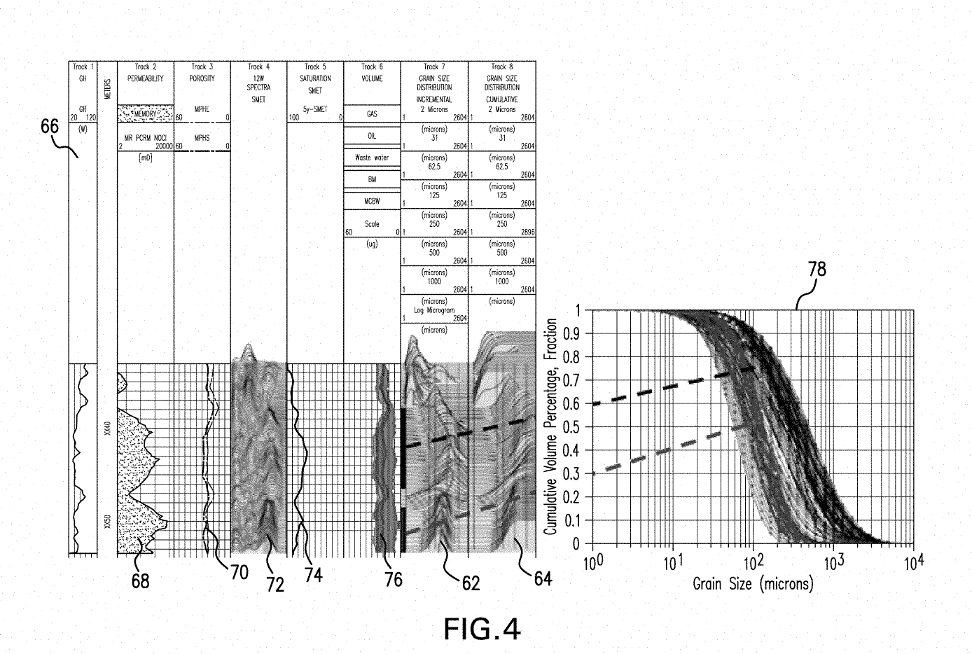

As shown in FIG. 4, the grain size distribution may be plotted in a log as a function of depth (or distance along a borehole trajectory). FIG. 4 shows an example of a grain size distribution log 62 and a cumulative grain size distribution log 64. In this example, the distribution logs are displayed with addition logging information in the form of a gamma ray log 66, a NMR permeability log 68, a NMR porosity log 70, simulated T_{2w} distribution 72, a fluid saturation log 74, and fluid volumetrics 76. The cumulative grain size distribution may be plotted for a selected interval (shown as plot 78), color coded for different depth ranges, to allow for inspection of the variation in grain size by depth.

In the fourth stage 44, porosity values are calculated based on the grain size distribution. The porosity is calculated based on a number of considerations, recognizing that knowledge and experience from material science is not necessarily applicable to rocks types of all kinds. For example, in crystalline rocks (e.g., granite, marble or crystalline calcitic limestone) finer grain sizes give rise to higher contact surface area, higher co-ordination numbers, and thus higher strength.

However, it has been discovered that this relationship between grain size and strength is not necessarily applicable to unconventional sandstone or other sedimentary formation. In some formations, particularly those having a sand, silt and/or shaly environment, smaller grain size can be associated with higher porosity and lower strength, due to a number of behaviors unique to this environment. One behavior is that well-rounded grain contacts at grain asperities causes higher porosity. As a result, smaller grain sizes can be associated with lower strength, in contrast to crystalline rocks.

Furthermore, finer grain sizes can result in contamination with clay content. The presence of even small amounts of clay causes a significant reduction in strength or stiffness, and increases in clay content are associated with decreases in strength. This susceptibility to clay intrusion can cause strength to decrease with smaller grain sizes.

Accordingly, in one embodiment, porosity is calculated based on a calibration that correlates grain size with porosity. For example, grain size distribution or values are correlated according to a function that relates porosity with grain size according to an inverse relationship.

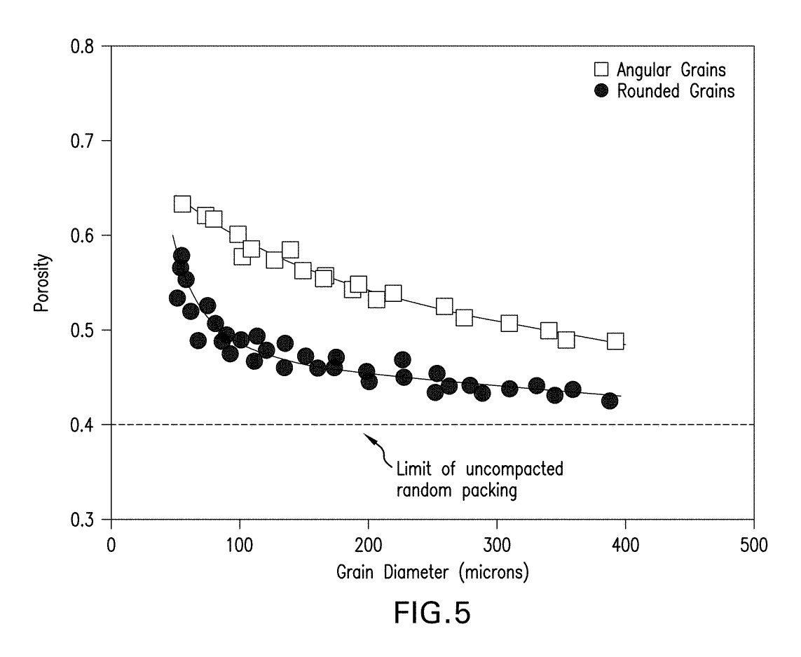

Sedimentary formations such as sandstone formations include sand grains that can differ in size, texture and geometry. Different grain sizes can be described according to different degrees of sorting, such as very well sorted, well sorted, moderately sorted, poorly sorted and very poorly sorted. The calibration is based on observations that sedimentary formations such as sandstone formations are generally at least well sorted. If the grains are spherical, porosity is independent of grain size; however grains tend to be less spherical as they are smaller, which can cause poorer packing and accordingly higher porosity. Accordingly, the calibration function is an inverse function in which porosity decreases with increasing grain size. An example of a function used to calibrate grain size to porosity is shown in FIG. 5. As shown, the function describes an inverse relationship between grain size and porosity, i.e., porosity decreases as grain diameter increases.

In addition to, or in place of, calculating porosity based on grain size, porosity may be calculated based on the echo trains. In one embodiment, the echo trains are processed to calculate porosity values (referred to as NMR porosity) for the region of interest. For example, the measured data (spin echo trains) are multiplied by a calibration factor to transform arbitrary units into porosity units. This porosity calculation may be used to estimate mechanical properties as discussed below and/or used to verify or refine the porosity calculated based the grain size distribution.

In the fifth stage 45, the NMR measurements are used to estimate mechanical properties of the region of interest. The mechanical properties that may be estimated include strength, stiffness and/or brittleness. Properties such as strength and/or brittleness may be used to identify sweet spots for selecting intervals through which stimulation and/or production are performed.

Strength and/or stiffness may be estimated based on porosity and/or grain size. Strength properties may include confined compressive strength (CCS) and/or unconfined compressive strength (UCS).

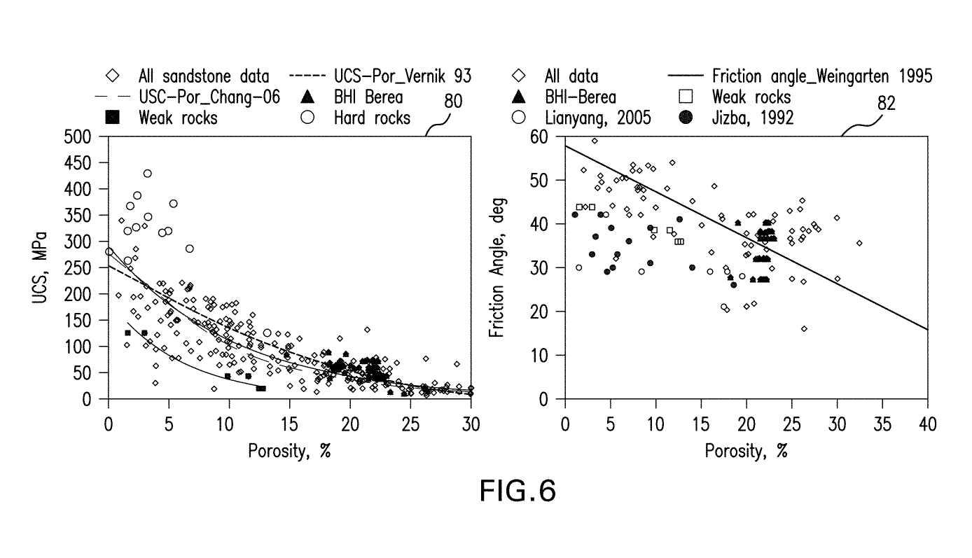

In one embodiment, porosity values are correlated with strength according to a relationship or function, which can be derived from empirical data or other information. FIG. 6 includes a plot 80 showing an example of UCS vs. porosity data for different formations and rock types. From this data, one or more curves are derived, and can be customized based on different formation features. In this example, UCS and porosity measurements taken from a number of sandstone formations are correlated and analyzed by curve fitting, regression or other type of analysis. The resulting curves may be used to estimate UCS from porosity calculated according to embodiments described herein.

Other properties related to strength can also be calculated using porosity. FIG. 6 shows an example of a plot 82 of porosity data as a function of friction angle, from which a curve or function is derived. Friction angle can thus be calculated based on porosity.

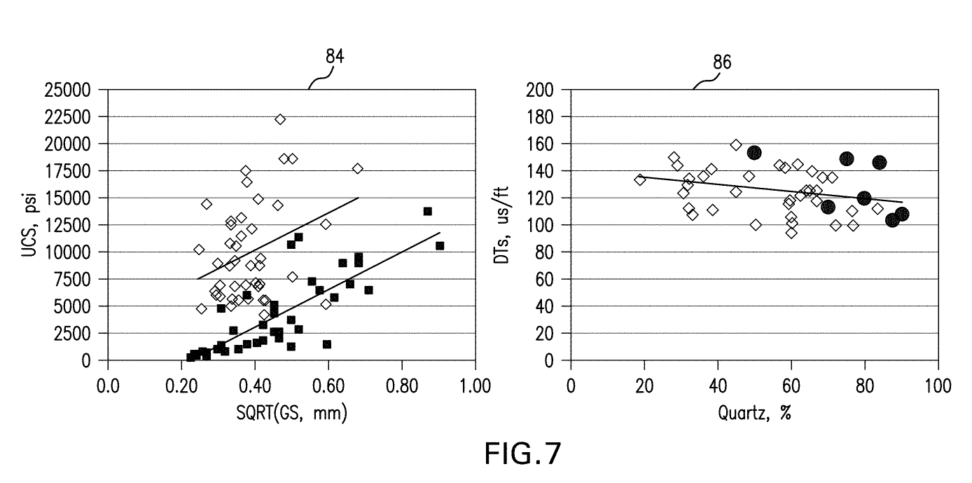

In one embodiment, grain size distributions or values are used to estimate strength properties. Grain sizes may be correlated with strength according to a relationship or function, which can be derived from empirical data or other information. An example of a function relating grain size to UCS is shown derived from a plot 84 of FIG. 7. As shown, the function describes a direct relationship between UCS and grain size (GS), i.e., UCS increases with increasing grain size.

In one embodiment, strength properties and/or other mechanical properties are analyzed to identify locations and extents of sweet spots. Sweet spots are formation regions that are most amenable to stimulation, to facilitate hydraulic fracturing or other stimulation operations. Sweet spots may be correlated with regions of low strength and/or high brittleness. Brittleness is a measurement of stored energy before failure, and is a function of parameters and properties such as rock strength, lithology, texture, effective stress, temperature, fluid type, diagenesis and TOC.

For example, regions of relatively low strength (e.g., relatively low UCS) are identified as sweet spots. Additional information can be used to identify sweet spots, such as mineralogy information (e.g., clay and/or quartz content). FIG. 7 includes a plot 86 that shows how the mineralogy of quartz content could be used to identify shear slowness, which can be an indication of sweet spot or brittleness.

In the sixth stage 46, aspects of an energy industry operation are performed based on the mechanical properties of the formation. Examples of an energy industry operation include drilling, stimulation, formation evaluation, measurement and/or production operations. For example, the mechanical properties are used to plan a drilling operation (e.g., trajectory, bit and equipment type, mud composition, rate of penetration, etc.) and may also be used to monitor the operation in real time and adjust operational parameters (e.g., bit rotational speed, fluid flow).

In one embodiment, the strength and stiffness properties are used as inputs into a mathematical model of the formation. In one embodiment, the strength and stiffness properties are used as inputs into a geomechanical model, which may be generated and/or updated in real time or near real time based on real time NMR measurements during drilling. The strength and stiffness properties may be used in addition to other data for generating the geomechanical model, such as drilling parameter data (e.g., rate of penetration), NMR porosity, and rig-site mineralogical data.

In reservoirs where secondary quartz deposition during diagenesis/post-diagenesis is very low, embodiments described herein can be highly effective for hydraulic fracture zone selection. By integrating laboratory sedimentological, mineralogical, grain size distribution, NMR and rock mechanical test interpretations along with NMR and other open-hole logs, quality of the reservoir as well as brittleness interpretations can be further improved for decision support on fracturing.

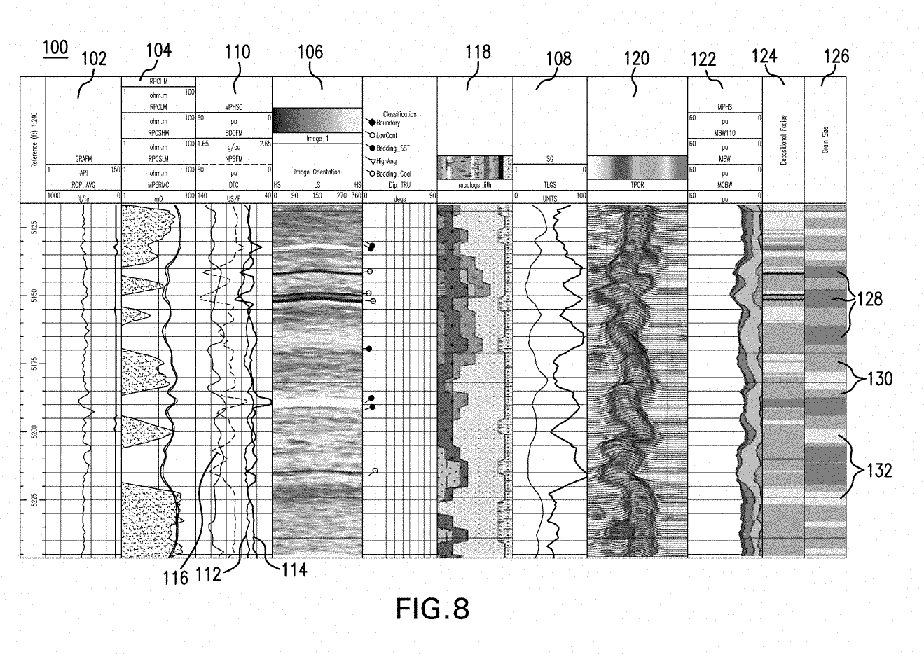

FIG. 8 illustrates an example of an integrated log 100 that includes NMR derived property logs and grain size properties estimated as discussed herein. The log 100 includes a gamma ray log 102, a resistivity log 104, an image log 106 (e.g., from gamma ray or density images), and a borehole gravity log 108. The log 100 also includes a porosity log 110 that includes log data for NMR porosity (MPHSC, curve 112), density (BDCFM, curve 114) and neutron porosity (NPSFM, curve 116).

The log 100 includes a mud log lithology log 118 showing relative percentages of minerals and other formation constituents estimated from mud log data, a T₂ distribution log 120, and a T₂ log 122 that shows volumetrics of various fluids derived from T₂ distributions (e.g., bound water and clay bound water). A depositional facies log 124 shows facies types as a function of depth. In this example, the facies types are color-coded, and show, e.g., coal (black), shale (red), sandy shale, shaly sandstone and sandstone. A grain size log 126 calculated, e.g., from NMR data as discussed herein, shows the grain size distribution as a function of depth. In this example, the grain size was correlated with or otherwise used to identify different grain types, and grain types were color-coded to show clay (red), silt (green) and sand (yellow). Regions 128 are regions characterized by clay, regions 130 are characterized by silt, and regions 132 are characterized by sand.

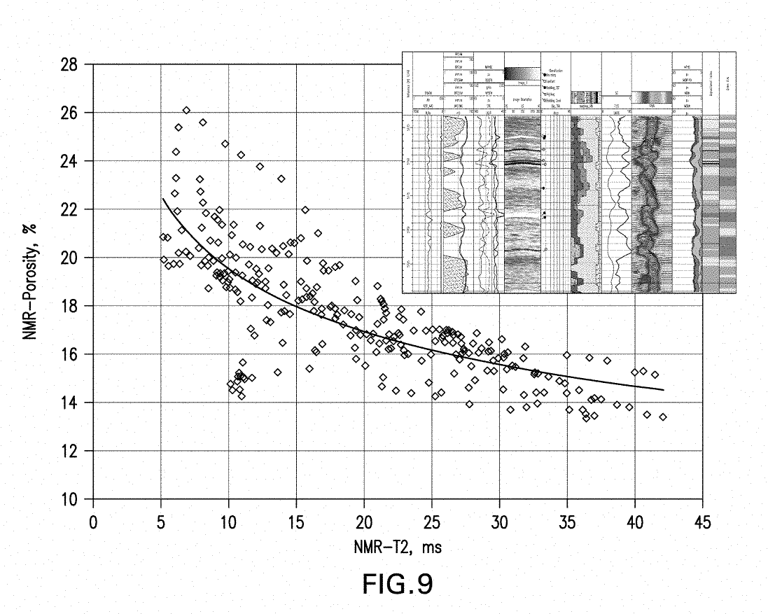

FIG. 9 shows an example of a portion of NMR measurement data used to estimate properties such as grain size shown in the log 100. NMR data points are plotted according to T₂ relaxation time, and spin echo amplitude is calibrated to porosity (NMR-porosity).

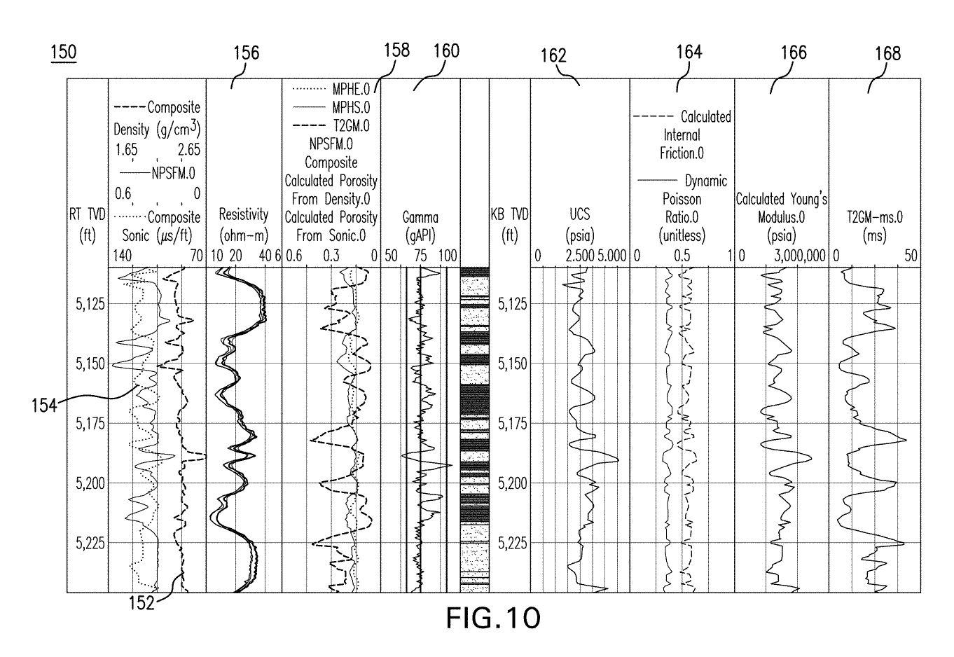

FIG. 10 shows an example of log data 150 related to mechanical properties of a formation. One or more or the logs of the log data 150 may be derived based on NMR measurements as discussed herein and/or in combination with other measurements. The log data of FIG. 10 is derived based on the measurements associated with the integrated log 100, and may be delivered and/or displayed with the log 100 to provide more comprehensive information regarding the formation and fluids therein.

The log data 150 in this example includes a density log 152, an acoustic or sonic log 154, a resistivity log 156, a porosity log 158 and a gamma ray log 160. Mechanical property data, all or some of which may be estimated based on NMR measurements as discussed herein, includes a UCS log 162, an internal friction log 164, and a stiffness or Young's Modulus log 166, which are displayed with a T₂ log 168 showing the geometric mean of the T₂ distribution as a function of depth.

The apparatuses, systems and methods described herein provide numerous advantages. The embodiments described herein provide effective techniques for estimating mechanical properties of rock, such as strength and stiffness, using NMR measurements. The embodiments allow for estimation of such mechanical properties exclusively through NMR measurements, during planning and/or operation phases. This is a significant advantage, as the rock mechanical properties discussed herein traditionally have been derived using different disciplines. For example, strength and stiffness have traditionally been estimated using mainly acoustic wave properties, and brittleness and sweet spot estimates have traditionally been generated using mineralogical data.

Furthermore, traditional measurement techniques employed in unconventional formations can be insufficient. For example, properties of unconventional sedimentary formations such as shaliness, siltiness, fine to very fine grain-size distribution of rock type, grain shape, grain-sorting and grain-packing may not be characterized fully using traditional logs of gamma ray, resistivity and acoustics. The embodiments described herein provide apparatuses, systems and methods for estimating these properties using NMR measurements alone or in combination with other measurement regimes to provide a more reliable and accurate estimate of mechanical properties, in particular for unconventional sedimentary formations, than traditional measurement schemes.

Set forth below are some embodiments of the foregoing disclosure:

### Embodiment 1

An apparatus for estimating properties of an earth formation, the apparatus comprising: a carrier configured to be deployed in a borehole in the earth formation; a nuclear magnetic resonance (NMR) measurement device including a transmitting assembly configured to emit a pulse sequence into a region of a sedimentary earth formation, and a receiving assembly configured to detect NMR signals in response to the pulse sequence; and a processor configured to receive the NMR signals and estimate one or more mechanical properties of the region, the processor configured to perform: calculating a size distribution based on the NMR signals, the size distribution including at least one of a pore size distribution and a grain size distribution in the region; estimating a strength of the region based on the size distribution; and performing one or more aspects of an energy industry operation based on the strength.

### Embodiment 2

The apparatus of embodiment 1, wherein the sedimentary formation is a sandstone formation.

### Embodiment 3

The apparatus of embodiment 1, wherein the processor is configured to perform estimating a porosity of the region based on the size distribution.

### Embodiment 4

The apparatus of embodiment 3, wherein the porosity is estimated based on a function describing an inverse relationship between porosity and grain size.

### Embodiment 5

The apparatus of embodiment 4, wherein the strength is estimated based on a function describing an inverse relationship between porosity and compressive strength.

### Embodiment 6

The apparatus of embodiment 1, wherein the strength is estimated based on a function describing a direct relationship between compressive strength and grain size.

### Embodiment 7

The apparatus of embodiment 1, wherein the strength is estimated for a plurality of locations along a trajectory of the borehole, and the processor is configured to further perform identifying one or more of the locations as sweet spots, the one or more sweet spots corresponding to regions of low strength relative to other locations.

### Embodiment 8

The apparatus of embodiment 7, wherein the processor is configured to estimate shear slowness at the plurality of locations based on mineralogy data, and identify the one or more sweet spots based on the strength and the shear slowness.

### Embodiment 9

The apparatus of embodiment 1, wherein the processor is configured to invert the NMR signals into a transverse relaxation time (T2) distribution, and calculate the size distribution based on the T2 distribution.

### Embodiment 10

The apparatus of embodiment 9, wherein the processor is configured to divide the T2 distribution into volumetrics including a volumetric associated with bound water, and calculate the size distribution based on the volumetric.

### Embodiment 11

A method of estimating properties of an earth formation, the method comprising: receiving NMR signals generated by a nuclear magnetic resonance (NMR) measurement device disposed in a carrier in a region of a sedimentary earth formation, the NMR measurement device including a transmitting assembly configured to emit a pulse sequence into a region of a sedimentary formation, and a receiving assembly configured to detect the NMR signals in response to the pulse sequence; and calculating a size distribution based on the NMR signals, the size distribution including at least one of a pore size distribution and a grain size distribution in the region; estimating a strength of the region based on the size distribution; and performing one or more aspects of an energy industry operation based on the strength.

### Embodiment 12

The method of embodiment 11, wherein the sedimentary formation is a sandstone formation.

### Embodiment 13

The method of embodiment 11, further comprising estimating a porosity of the region based on the size distribution.

### Embodiment 14

The method of embodiment 13, wherein the porosity is estimated based on a function describing an inverse relationship between porosity and grain size.

### Embodiment 15

The method of embodiment 14, wherein the strength is estimated based on a function describing an inverse relationship between porosity and compressive strength.

### Embodiment 16

The method of embodiment 11, wherein the strength is estimated based on a function describing a direct relationship between compressive strength and grain size.

### Embodiment 17

The method of embodiment 11, wherein the strength is estimated for a plurality of locations along a trajectory of the borehole, the method further comprising identifying one or more of the locations as sweet spots, the one or more sweet spots corresponding to regions of low strength relative to other locations.

### Embodiment 18

The method of embodiment 17, wherein the processor is configured to estimate shear slowness at the plurality of locations based on mineralogy data, and identify the one or more sweet spots based on the strength and the shear slowness.

### Embodiment 19

The method of embodiment 11, wherein receiving the NMR signals includes inverting the NMR signals into a transverse relaxation time (T2) distribution, the size distribution calculated based on the T2 distribution.

### Embodiment 20

The method of embodiment 19, wherein receiving the NMR signals includes dividing the T2 distribution into volumetrics including a volumetric associated with bound water, the size distribution calculated based on the volumetric.

In connection with the teachings herein, various analyses and/or analytical components may be used, including digital and/or analog subsystems. The system may have components such as a processor, storage media, memory, input, output, communications link (wired, wireless, pulsed mud, optical or other), user interfaces, software programs, signal processors and other such components (such as resistors, capacitors, inductors, etc.) to provide for operation and analyses of the apparatus and methods disclosed herein in any of several manners well-appreciated in the art. It is considered that these teachings may be, but need not be, implemented in conjunction with a set of computer executable instructions stored on a computer readable medium, including memory (ROMs, RAMs), optical (CD-ROMs), or magnetic (disks, hard drives), or any other type that when executed causes a computer to implement the method of the present invention. These instructions may provide for equipment operation, control, data collection and analysis and other functions deemed relevant by a system designer, owner, user, or other such personnel, in addition to the functions described in this disclosure.

One skilled in the art will recognize that the various components or technologies may provide certain necessary or beneficial functionality or features. Accordingly, these functions and features as may be needed in support of the appended claims and variations thereof, are recognized as being inherently included as a part of the teachings herein and a part of the invention disclosed.

While the invention has been described with reference to exemplary embodiments, it will be understood by those skilled in the art that various changes may be made and equivalents may be substituted for elements thereof without departing from the scope of the invention. In addition, many modifications will be appreciated by those skilled in the art to adapt a particular instrument, situation or material to the teachings of the invention without departing from the essential scope thereof. Therefore, it is intended that the invention not be limited to the particular embodiment disclosed as the best mode contemplated for carrying out this invention.

What is claimed is:

1. An apparatus for estimating properties of an earth formation, the apparatus comprising:
a carrier configured to be deployed in a borehole in the earth formation;
a nuclear magnetic resonance (NMR) measurement device including a transmitting assembly configured to emit a pulse sequence into a region of a sedimentary earth formation, and a receiving assembly configured to detect NMR signals in response to the pulse sequence; and
a processor configured to receive the NMR signals and estimate one or more mechanical properties of the region, the processor configured to perform:
calculating a size distribution based on the NMR signals, the size distribution including at least one of a pore size distribution and a grain size distribution in the region;
estimating a strength of the region based on the size distribution; and
performing one or more aspects of an energy industry operation based on the strength.

2. The apparatus of claim 1, wherein the sedimentary formation is a sandstone formation.

3. The apparatus of claim 1, wherein the processor is configured to perform estimating a porosity of the region based on the size distribution.

4. The apparatus of claim 3, wherein the porosity is estimated based on a function describing an inverse relationship between porosity and grain size.

5. The apparatus of claim 4, wherein the strength is estimated based on a function describing an inverse relationship between porosity and compressive strength.

6. The apparatus of claim 1, wherein the strength is estimated based on a function describing a direct relationship between compressive strength and grain size.

7. The apparatus of claim 1, wherein the strength is estimated for a plurality of locations along a trajectory of the borehole, and the processor is configured to further perform identifying one or more of the locations as sweet spots, the one or more sweet spots corresponding to regions of low strength relative to other locations.

8. The apparatus of claim 7, wherein the processor is configured to estimate shear slowness at the plurality of locations based on mineralogy data, and identify the one or more sweet spots based on the strength and the shear slowness.

9. The apparatus of claim 1, wherein the processor is configured to invert the NMR signals into a transverse relaxation time (T₂) distribution, and calculate the size distribution based on the T₂ distribution.

10. The apparatus of claim 9, wherein the processor is configured to divide the T₂ distribution into volumetrics including a volumetric associated with bound water, and calculate the size distribution based on the volumetric.

11. A method of estimating properties of an earth formation, the method comprising:
receiving NMR signals generated by a nuclear magnetic resonance (NMR) measurement device disposed in a carrier in a region of a sedimentary earth formation, the NMR measurement device including a transmitting assembly configured to emit a pulse sequence into a region of a sedimentary formation, and a receiving assembly configured to detect the NMR signals in response to the pulse sequence;
calculating a size distribution based on the NMR signals, the size distribution including at least one of a pore size distribution and a grain size distribution in the region;
estimating a strength of the region based on the size distribution; and
performing one or more aspects of an energy industry operation based on the strength.

12. The method of claim 11, wherein the sedimentary formation is a sandstone formation.

13. The method of claim 11, further comprising estimating a porosity of the region based on the size distribution.

14. The method of claim 13, wherein the porosity is estimated based on a function describing an inverse relationship between porosity and grain size.

15. The method of claim 14, wherein the strength is estimated based on a function describing an inverse relationship between porosity and compressive strength.

16. The method of claim 11, wherein the strength is estimated based on a function describing a direct relationship between compressive strength and grain size.

17. The method of claim 11, wherein the strength is estimated for a plurality of locations along a trajectory of the borehole, the method further comprising identifying one or more of the locations as sweet spots, the one or more sweet spots corresponding to regions of low strength relative to other locations.

18. The method of claim 17, wherein the processor is configured to estimate shear slowness at the plurality of locations based on mineralogy data, and identify the one or more sweet spots based on the strength and the shear slowness.

19. The method of claim 11, wherein receiving the NMR signals includes inverting the NMR signals into a transverse relaxation time (T₂) distribution, the size distribution calculated based on the T₂ distribution.

20. The method of claim 19, wherein receiving the NMR signals includes dividing the T2 distribution into volumetrics including a volumetric associated with bound water, the size distribution calculated based on the volumetric.
